(19) United States
(12) Patent Application Publication
(10) Pub. No.: US 2011/0017288 A1
(43) Pub. Date: Jan. 27, 2011

(54) Thin film type solar cell and method of manufacturing the same

(75) Inventors: Kyoung-Jin Jeong, Suwon (KR); Donghoon Kim, Seongnam (KR); Jaewoo Joung, Suwon (KR); Sungil Oh, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/654,435

(22) Filed: Dec. 18, 2009

(30) Foreign Application Priority Data
Jul. 21, 2009 (KR) 10-2009-0066417

(51) Int. Cl. H01L 31/0236; H01L 31/18

(52) U.S. Cl. 136/256; 438/71; 257/E31.13

(57) ABSTRACT

There is provided a thin film type solar cell including: a crystalline silicon wafer subject to surface texturing and forming an n-type semiconductor layer; a pn junction formed of a non-crystalline p-type silicon layer deposited on one surface of the crystalline silicon wafer and a non-crystalline n-type silicon layer deposited on the other surface thereof; a transparent surface electrode formed outward of the pn junction; a water repellent light transmitting layer formed on the pn junction, the surface electrode, or both the pn junction and the surface electrode and allowing for an increase in light transmittance; and a pattern electrode formed on the surface electrode or the water repellent light transmitting layer.

### CROSS-REFERENCE TO RELATED APPLICATIONS

This application claims the priority of Korean Patent Application No. 10-2009-0066417 filed on Jul. 21, 2009, in the Korean Intellectual Property Office, the disclosure of which is incorporated herein by reference.

### BACKGROUND OF THE INVENTION

1. Field of the Invention

The present invention relates to a thin film type solar cell and a method of manufacturing the same, and more particularly, to a thin film type solar cell allowing for an increase in light transmittance and a reduction in specific resistance by forming a light transmitting thin film on a crystalline silicon wafer and a method of manufacturing the thin film type solar cell.

2. Description of the Related Art

A solar cell along with a fuel cell is currently in the spotlight as being able to produce “green,” or environmentally friendly, energy able to reduce global warming and be substituted for fossil fuel energy which will, in the future, be exhausted.

A solar cell converts light energy into electrical energy using semiconductor characteristics.

Such a solar cell has a pn junction structure having a p-type semiconductor and an n-type semiconductor joined together. When the solar cell having such a pn junction structure is exposed to sunlight having a greater energy band gap than that of the semiconductors, holes and electrons are generated in the semiconductors by the energy of the incident sunlight. At this time, due to electric field generated in the pn junction, the holes(+) move toward the p-type semiconductor and the electrons(−) move toward the n-type semiconductor, resulting in the creation of electric potential, whereby photoelectromotive force is generated. Then, the electrodes at both ends of the pn junction are connected to a load, current flows therethrough, thereby generating electric power.

Meanwhile, a solar cell may be classified as either a substrate type solar cell or a thin film type solar cell.

The substrate type solar cell is manufactured by using a semiconductor material, such as silicon, as a substrate, while the thin film type solar cell is manufactured by forming a semiconductor to be a thin film on a substrate formed of a material such as glass.

The substrate type solar cell has somewhat higher efficiency than the thin film type solar cell. However, the substrate type solar cell has a limitation in the minimization of thickness and an increase in manufacturing costs due to the use of a relatively expensive semiconductor substrate.

On the other hand, the thin film type solar cell has somewhat reduced efficiency as compared to the substrate type solar cell. However, in comparison to the substrate type solar cell, the thin film type solar cell may be manufactured to allow for a greatly reduced thickness as well as a reduction in manufacturing costs due to the use of a cheaper material.

Recently, with rising silicon prices due to a shortage of silicon, a material which is an essential component of the substrate type solar cell, growing attention has been drawn to the thin film type solar cell. Notably, studies have been conducted vigorously on an HIT (heterojunction with intrinsic thin layer) solar cell in which non-crystalline silicon thin films are formed on both surfaces of a crystalline silicon substrate respectively.

Such an HIT solar cell is very efficient in converting sunlight into electrical energy. Various attempts have been made to further increase the efficiency of the solar cell.

Therefore, there is a need for studies focused on a method of manufacturing a solar cell with higher efficiency in order to increase overall efficiency.

### SUMMARY OF THE INVENTION

An aspect of the present invention provides a method of manufacturing a thin film type solar cell allowing for an increase in light transmittance and a reduction in specific resistance by forming a light transmitting thin film on a crystalline silicon wafer.

According to an aspect of the present invention, there is provided a thin film type solar cell, the thin film type solar cell including: a crystalline silicon wafer subject to surface texturing and forming an n-type semiconductor layer; a pn junction formed of a non-crystalline p-type silicon layer deposited on one surface of the crystalline silicon wafer and a non-crystalline n-type silicon layer deposited on the other surface thereof; a transparent surface electrode formed outward of the pn junction; a water repellent light transmitting layer formed on the pn junction, the surface electrode, or both the pn junction and the surface electrode and allowing for an increase in light transmittance; and a pattern electrode formed on the surface electrode or the water repellent light transmitting layer.

The crystalline silicon wafer may be formed of glass or transparent plastic.

The water repellent light transmitting layer may be formed of a fluoro-based material.

The pattern electrode may have a paste or ink pattern having a small width and formed of at least one of Ag, Cu, Ni, Au and an alloy thereof.

The surface electrode may be formed of a transparent conductive material such as ZnO, ZnO:B, ZnO:Al, ZnO:H, SfO₂, SnO₂:F or ITO.

According to another aspect of the present invention, there is provided a method of manufacturing a thin film type solar cell, the method including: surface texturing a crystalline silicon wafer forming an n-type semiconductor layer; forming a pn junction by depositing a non-crystalline p-type silicon layer on one surface of the crystalline silicon wafer and a non-crystalline n-type silicon layer on the other surface thereof; forming a transparent surface electrode outward of the pn junction; forming a water repellent light transmitting layer allowing for increasing light transmittance on the surface electrode; and forming a pattern electrode on the surface electrode or the water repellent light transmitting layer.

Another water repellent light transmitting layer may be additionally formed on the pn junction in order to further increase light transmittance.

The water repellent light transmitting layer may be formed by spray coating, brushing, dipping, spin coating, inkjet printing, or roll to roll printing.

The water repellent light transmitting layer may be formed of a fluoro-based material.

The pattern electrode may have a paste or ink pattern having a small width and formed of at least one of Ag, Cu, Ni, Au and an alloy thereof.

The pattern electrode may be formed by electroplating, electroless plating, or chemical plating using Cu, Ag, Au, or Ni.

The pattern electrode may be formed by a jetting method or a printing method.

The pattern electrode may be formed of a transparent conductive material such as ZnO, ZnO:B, ZnO:Al, ZnO:H, SnO₂, SnO₂:F or ITO.

The method may further include drying or densifying the pattern electrode by using heat treatment, UV treatment, plasma treatment, or microwave treatment.

According to another aspect of the present invention, there is provided a method of manufacturing a thin film type solar cell, the method including: surface texturing a crystalline silicon wafer forming an n-type semiconductor layer; forming a pn junction by depositing a non-crystalline p-type silicon layer on one surface of the crystalline silicon wafer and a non-crystalline n-type silicon layer on the other surface thereof; forming a water repellent light transmitting layer allowing for increasing light transmittance on the pn junction; forming a transparent surface electrode on the water repellent light transmitting layer; and forming a pattern electrode on the surface electrode.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view illustrating a thin film type solar cell according to an exemplary embodiment of the present invention;

FIGS. 2A through 2F are schematic cross-sectional views illustrating a method of manufacturing a thin film type solar cell according to an exemplary embodiment of the present invention; and

FIG. 3 illustrates graphs comparing a graph (a) illustrating the light transmittance of a thin film type solar cell before water repellency treatment according to related art with a graph (b) illustrating the light transmittance of a thin film type solar cell after water repellency treatment according to an exemplary embodiment of the present invention and a graph (c) illustrating the light transmittance of a thin film type solar cell after heat treatment according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions may be exaggerated for clarity.

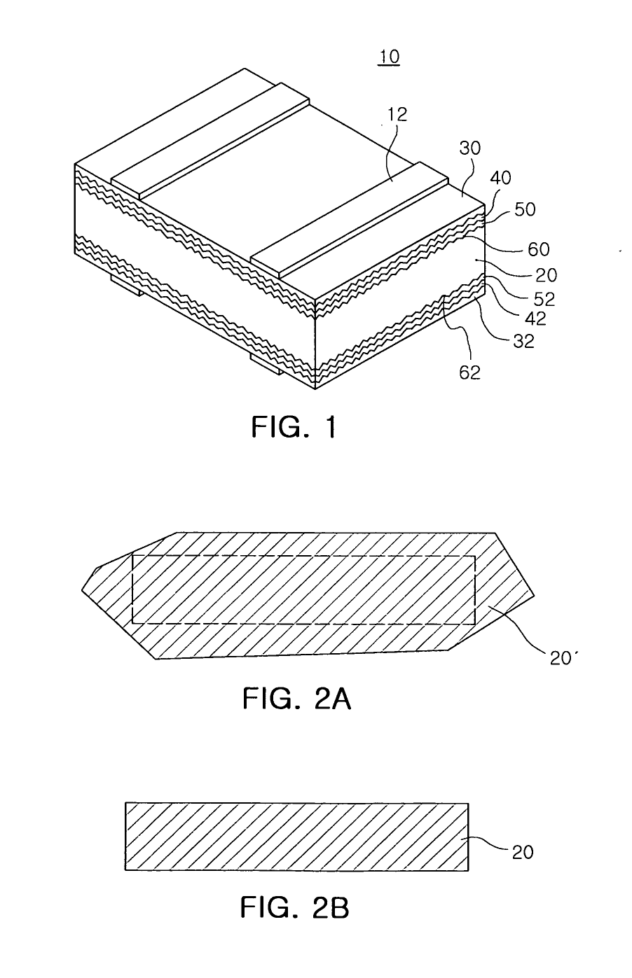

FIG. 1 is a schematic perspective view illustrating a thin film type solar cell according to an exemplary embodiment of the present invention.

Referring to FIG. 1, a thin film type solar cell 10 includes a crystalline silicon wafer 20, pn junctions 20, 50 and 52, surface electrodes 40 and 42, water repellent light transmitting layers 30 and 32, and pattern electrodes 12.

Both surfaces of the crystalline silicon wafer 20 may be subject to surface texturing to thereby form textured surfaces 60 and 62 having a minutely uneven texture. This may cause multiple reflections of sunlight and substantially reduce reflectance. Also, the crystalline silicon wafer 20, which is an n-type semiconductor, may be formed of glass or transparent plastic.

On the textured surfaces 60 and 62 of the crystalline silicon wafer 20, a non-crystalline p-type silicon layer 50 may be formed as a thin film by using plasma-enhanced chemical vapor deposition (PECVD) on one upper textured surface 60.

Also, a non-crystalline n-type silicon layer 52 may be formed as a thin film by using PECVD on the other textured surface 62.

That is, the crystalline silicon wafer 20, which is an n-type semiconductor layer, has the non-crystalline p-type and n-type semiconductor layers 50 and 52 deposited thereon, thereby forming a pn junction.

Due to electric field generated in the pn junction, holes(+) move toward a p-type semiconductor and electrons(−) move toward an n-type semiconductor, resulting in the creation of electric potential, whereby photoelectromotive force is generated.

The water repellent light transmitting layers 30 and 32 may be formed on the surface electrodes 40 and 42 to thereby improve light transmittance. Here, the water repellent light transmitting layers 30 and 32 may be formed on the surfaces of the pn junction, as well as the surface electrodes 40 and 42.

Also, the water repellent light transmitting layers 30 and 32 may be formed on the surfaces of the pn junction and the surface electrodes 40 and 42 at the same time.

The water repellent light transmitting layers 30 and 32 may be formed of a fluoro-based material. Particularly, they are formed as water repellent layers by being coated with an organic solvent of a fluorine-containing surfactant such as hexa-fluor-ethylene (HFE).

In this manner, the water repellent light transmitting layers 30 and 32 may increase incidental light absorption, whereby overall light transmittance may be enhanced.

The surface electrodes 40 and 42 may be formed of a transparent conductive material such as ZnO, ZnO:B, ZnO:Al, ZnO:H, SnO₂, SnO₂:F or ITO.

The pattern electrodes 12 may be formed on the surface electrodes 40 and 42 and their patterns may be a silver paste pattern having a small width.

Accordingly, in the thin film type solar cell 10 configured as above, when the pattern electrodes 12 at both ends of the pn junction are connected to a load, current flows therethrough, and thus electric power may be generated.

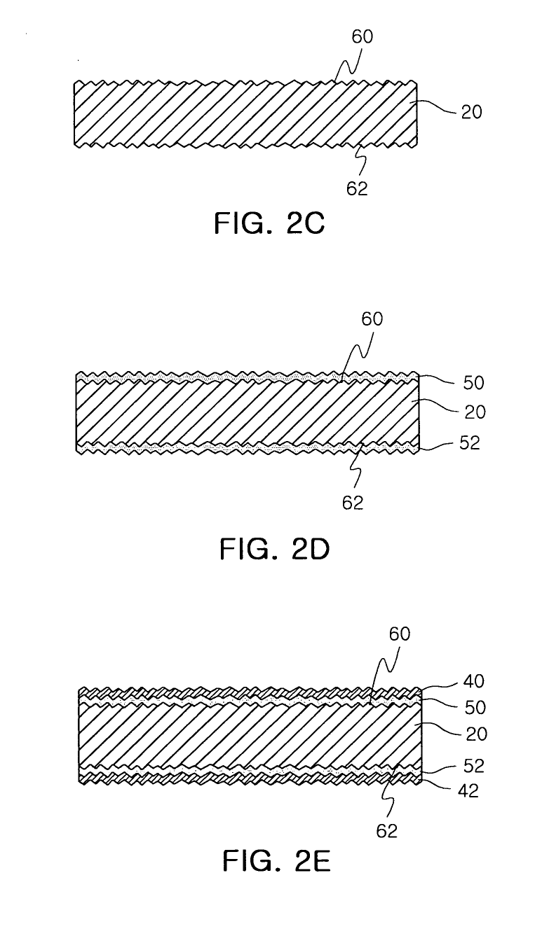

FIGS. 2A through 2F are schematic cross-sectional views illustrating a method of manufacturing a thin film type solar cell according to an exemplary embodiment of the present invention.

As shown in FIG. 2A, a crystalline silicon wafer 20′, which is an n-type semiconductor, is initially cleaned and subject to surface treatment such as cutting or grinding. As shown in FIG. 2B, a flat crystalline silicon wafer 20 is prepared.

The crystalline silicon wafer 20 is subject to surface texturing to thereby form the textured surfaces 60 and 62 as shown in FIG. 2C.

Also, as shown in FIG. 2D, the crystalline silicon wafer 20 has the non-crystalline p-type silicon layer 50 deposited on one surface thereof and the non-crystalline n-type silicon layer 52 deposited on the other surface thereof, thereby forming a pn junction.

FIG. 2E illustrates the formation of the transparent surface electrodes 40 and 42 on both surfaces of the pn junction. Then, as shown in FIG. 2F, the water repellent light transmitting layers 30 and 32 may be formed on the surface electrodes 40 and 42, and the pattern electrodes 12 may be formed on the water repellent light transmitting layers 30 and 32.

In the present embodiment, the water repellent light transmitting layers 30 and 32 are formed on the surface electrodes 40 and 42, but they may be formed on the pn junction.

Also, the water repellent light transmitting layers 30 and 32 may be formed on the pn junction and the surface electrodes 40 and 42 at the same time.

The formation of the water repellent light transmitting layers 30 and 32 so as to increase sunlight transmittance is illustrated. Here, the water repellent light transmitting layers 30 and 32 may be formed by spray coating, brushing, dipping, spin coating, inkjet printing, or roll to roll printing.

Also, the water repellent light transmitting layers 30 and 32 may be formed of a fluoro-based material. Particularly, they may be formed by treating hexa-fluor-ethylene (HFE).

The surface electrodes 40 and 42 may be formed of a transparent conductive material such as ZnO, ZnO:B, ZnO:Al, ZnO:H, SnO₂, SnO₂:F or ITO.

The pattern electrodes 12 may have a paste or ink pattern having a small width and formed of at least one of Ag, Cu, Ni, Au and an alloy thereof.

Also, the pattern electrodes 12 may be formed by a jetting method or a printing method. For example, the jetting method may be dispenser or inkjet printing and the printing method may be screen printing or roll to roll printing.

The pattern electrodes 12 may be formed by electroplating, electroless plating, or chemical plating using Cu, Ag, Au, or Ni. Also, the pattern electrodes 12 may be formed by inkjet printing or screen printing.

Also, the thin film type solar cell of FIG. 2F may be dried or densified by the use of heat treatment, UV treatment, plasma treatment, or microwave treatment.

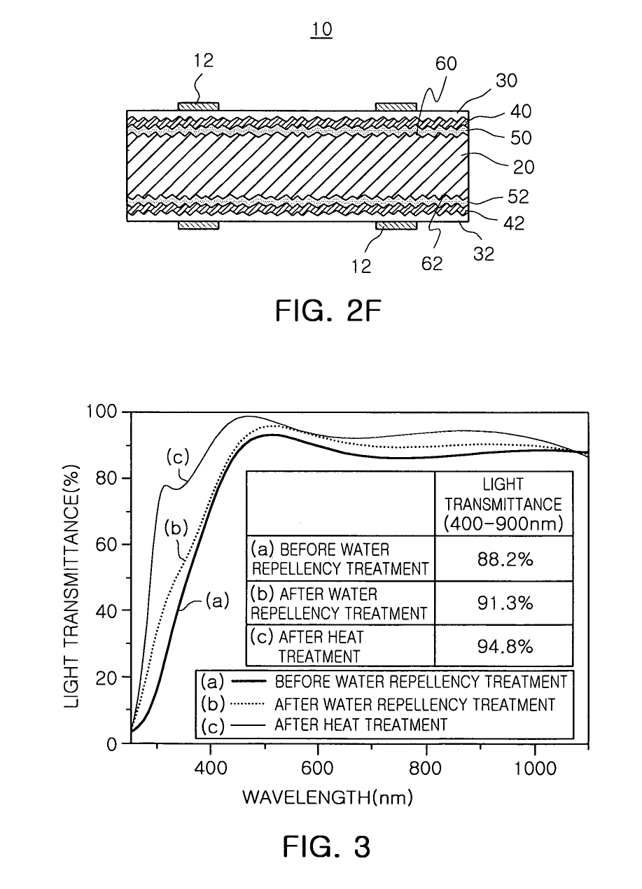

FIG. 3 shows graphs comparing a graph (a) illustrating the light transmittance of a thin film type solar cell before water repellency treatment according to related art with a graph (b) illustrating the light transmittance of a thin film type solar cell after water repellency treatment according to an exemplary embodiment of the invention and a graph (c) illustrating the light transmittance of a thin film type solar cell after heat treatment according to another exemplary embodiment of the invention.

Referring to FIG. 3, it is shown that the light transmittance, according to a wavelength band range, is demonstrated in the case of a conventional thin film type solar cell (a) without the formation of a water repellent light transmitting layer, a thin film type solar cell (b) including a water repellent light transmitting layer according to an exemplary embodiment of the invention, and a thin film type solar cell (c) which includes a water repellent layer and is finally subject to heat treatment according to another exemplary embodiment of the invention.

That is, it is understood that there is an increase in light transmittance across an entire range of wavelength bands in the case of the thin film type solar cell (b) including the water repellent light transmitting layer and the thin film type solar cell (c) which includes the water repellent layer and is finally subject to heat treatment, as compared to the conventional thin film type solar cell (a).

Particularly, it is understood that there is a remarkable increase in light transmittance in the short wavelength range below 400 nm in the case of (b) and (c) as compared to (a).

In the thin film type solar cell and the method of manufacturing the same according to exemplary embodiments of the invention, light transmittance may be increased by forming water repellent light transmitting layers on both surfaces of the pn junction, whereby the overall efficiency of the solar cell in converting solar energy into electrical energy is enhanced.

Also, the formation of the water repellent light transmitting layers leads to an increase in light transmittance across the entire range of wavelength bands of sunlight.

As set forth above, according to exemplary embodiments of the invention, light transmittance may be improved in such a manner that water repellent light transmitting layers allowing for an increase in light transmittance are formed on both surfaces of a pn junction, whereby the overall efficiency of a solar cell in converting sunlight into electrical energy is enhanced.

Also, sunlight transmittance across the entire range of wavelength bands is increased by forming the water repellent light transmitting layers.

While the present invention has been shown and described in connection with the exemplary embodiments, it will be apparent to those skilled in the art that modifications and variations can be made without departing from the spirit and scope of the invention as defined by the appended claims.

What is claimed is:

1. A thin film type solar cell comprising:
a crystalline silicon wafer subject to surface texturing and forming an n-type semiconductor layer;
a pn junction formed of a non-crystalline p-type silicon layer deposited on one surface of the crystalline silicon wafer and a non-crystalline n-type silicon layer deposited on the other surface thereof;
a transparent surface electrode formed outward of the pn junction;
a water repellent light transmitting layer formed on the pn junction, the surface electrode, or both the pn junction and the surface electrode and allowing for an increase in light transmittance; and
a pattern electrode formed on the surface electrode or the water repellent light transmitting layer.

2. The thin film type solar cell of claim 1, wherein the crystalline silicon wafer is formed of glass or transparent plastic.

3. The thin film type solar cell of claim 1, wherein the water repellent light transmitting layer is formed of a fluoro-based material.

4. The thin film type solar cell of claim 1, wherein the pattern electrode has a paste or ink pattern having a small width and is formed of at least one of Ag, Cu, Ni, Au and an alloy thereof.

5. The thin film type solar cell of claim 1, wherein the surface electrode is formed of a transparent conductive material such as ZnO, ZnO:B, ZnO:Al, ZnO: H, SnO₂, SnO₂:F or ITO.

6. A method of manufacturing a thin film type solar cell, the method comprising:
surface texturing a crystalline silicon wafer forming an n-type semiconductor layer;
forming a pn junction by depositing a non-crystalline p-type silicon layer on one surface of the crystalline silicon wafer and a non-crystalline n-type silicon layer on the other surface thereof;
forming a transparent surface electrode outward of the pn junction;
forming a water repellent light transmitting layer allowing for increasing light transmittance on the surface electrode; and
forming a pattern electrode on the surface electrode or the water repellent light transmitting layer.

7. The method of claim 6, wherein another water repellent light transmitting layer is additionally formed on the pn junction in order to further increase light transmittance.

8. The method of claim 6, wherein the water repellent light transmitting layer is formed by spray coating, brushing, dipping, spin coating, inkjet printing, or roll to roll printing.

9. The method of claim 6, wherein the water repellent light transmitting layer is formed of a fluoro-based material.

10. The method of claim 6, wherein the pattern electrode has a paste or ink pattern having a small width and is formed of at least one of Ag, Cu, Ni, Au and an alloy thereof.

11. The method of claim 6, wherein the pattern electrode is formed by electroplating, electroless plating, or chemical plating using Cu, Ag, Au, or Ni.

12. The method of claim 6, wherein the pattern electrode is formed by a jetting method or a printing method.

13. The method of claim 6, wherein the pattern electrode is formed of a transparent conductive material such as ZnO, ZnO:B, ZnO:Al, ZnO:H, SnO₂, SnO₂:F or ITO.

14. The method of claim 6, further comprising drying or densifying the pattern electrode by using heat treatment, UV treatment, plasma treatment, or microwave treatment.

15. A method of manufacturing a thin film type solar cell, the method comprising:
surface texturing a crystalline silicon wafer forming an n-type semiconductor layer;
forming a pn junction by depositing a non-crystalline p-type silicon layer on one surface of the crystalline silicon wafer and a non-crystalline n-type silicon layer on the other surface thereof;
forming a water repellent light transmitting layer allowing for increasing light transmittance on the pn junction;
forming a transparent surface electrode on the water repellent light transmitting layer; and
forming a pattern electrode on the surface electrode.
